(19) United States
(12) Patent Application Publication
(10) Pub. No.: US 2006/0221335 A1
(43) Pub. Date: Oct. 5, 2006

(54) Method and apparatus for interactive hyperspectral image subtraction

(76) Inventors: Arjun S. Bangalore, Monroeville, PA (US); David Tuschel, Monroeville, PA (US)

Correspondence Address: DUANE MORRIS LLP;Suite 700, 1667 K Street, N.W., Washington, DC, 20006, US

(21) Appl. No.: 11/097,160

(22) Filed: Apr. 4, 2005

(51) Int. Cl. H01L 27/00; G01J 3/44; G01N 21/65

(52) U.S. Cl. 356/301; 250/208.1

(57) ABSTRACT

The disclosure relates to method and apparatus for interactive hyperspectral image subtraction. In one embodiment, the disclosure relates to a method for obtaining a spectral image of a first specie from a frame of a plurality of pixels defining a composition of the first specie with a second specie. The method may include (i) identifying, for each of the first and second species, an appropriate Raman wavelength; (ii) defining at least one background wavelength for the frame; (iii) identifying pixels defined only by background wavelength; (iv) identifying pixels defined only by the first specie or the second specie; (v) identifying the remaining pixels, the remaining pixels defined by at least a combination of the first and second species; and (vi) forming a spectral image for the first specie.

### BACKGROUND

Spectroscopic imaging combines digital imaging and molecular spectroscopy techniques, which can include Raman scattering, fluorescence, photoluminescence, ultraviolet, visible and infrared absorption spectroscopies. When applied to the chemical analysis of materials, spectroscopic imaging is commonly referred to as chemical imaging. Instruments for performing spectroscopic (i.e., chemical) imaging typically comprise image gathering optics, focal plane array imaging detectors and imaging spectrometers.

In general, the sample size determines the choice of image gathering optic. For example, a microscope is typically employed for the analysis of sub micron to millimeter spatial dimension samples. For larger objects, in the range of millimeter to meter dimensions, macro lens optics are appropriate. For samples located within relatively inaccessible environments, flexible fiberscopes or rigid borescopes can be employed. For very large scale objects, such as planetary objects, telescopes are appropriate image gathering optics.

Often the sample under study includes a plurality of species in a mixture. Thus, the chemical image of the sample characterizes the sample as a mixture of species. Each specie can be a pure element, a compound of said element with other elements or a compound. While the chemical image of the sample can identify each of the species by using color or some other indication, it fails to communicate the spectral image of each specie independent of the mixture. Thus, there is a need for a method and apparatus to interactively obtain the spectral image for the desired specie from the chemical image of the mixture.

The instant disclosure addresses the needs described above. In one embodiment, the disclosure relates to a method for obtaining a spectral image of a first specie from a frame of a plurality of pixels defining a composition of the first specie with a second specie, comprising (i) identifying, for each of the first and second species, an appropriate Raman wavelength; (ii) defining at least one background wavelength for the frame; identifying pixels defined only by background wavelength; (iii) identifying pixels defined only by the first specie or the second specie; (iv) identifying the remaining pixels, the remaining pixels defined by at least a combination of the first and second species; (v) identifying the contribution from each of the first and the second specie for each of the remaining pixels; and (vi) forming a spectral image for the first specie.

In another embodiment, the disclosure relates to a method for obtaining a spectral image of first specie from a chemical image of said first specie in combination with a second specie. The method includes (i) providing a chemical image of a mixture of the first and second specie, the chemical image defined by a frame having a plurality of pixels; (ii) identifying, for each of the first and second species, an appropriate Raman wavelength; (iii) defining a background wavelength for the frame; (iv) identifying pixels defined only by background wavelength; (v) identifying pixels defined by the peak Raman wavelength of the first specie or the second specie; (vi) identifying a plurality of remaining pixels, the remaining pixels identifying a combination of the first and second species; (vii) identifying the contribution from each of the first and the second specie to each of the remaining pixels; and (viii) forming a spectral image for the first specie.

In still another embodiment, the disclosure relates to an apparatus for obtaining a spectral image of a first specie from a chemical image of said first specie admixed with a second specie. The apparatus includes: an illumination source for illuminating the sample with a plurality of excitation photons to produce a plurality of interacted photons; an optical device for receiving and directing the plurality of interacted photons to an imaging device for forming a chemical image define by at least one frame having a plurality of pixels; and a processor in communication with the imaging device. The processor can be adapted to execute instructions to (i) identify, for each of the first and second species, an appropriate Raman wavelength; define at least one background wavelength for the frame; (ii) identify pixels defined only by background wavelength; (iii) identify pixels defined only by the first specie or the second specie; (iv) identify the remaining pixels, the remaining pixels defined by at least a combination of the first and second species; (v) identify the contribution from each of the first and the second specie for each of the remaining pixels; and (vi) form a spectral image for the first specie.

### BRIEF DESCRIPTION OF THE DRAWINGS

FIG. 1 is a schematic chemical image of a sample having a combination of two species;

FIG. 2 shows peak Raman intensities and correlated wavelengths for each of the species shown in FIG. 1;

FIGS. 3A-3C illustrate the resulting spectrum from a chemical interaction of two spectra; and

FIG. 4 is a schematic illustration of an exemplary apparatus according to one embodiment of the disclosure.

### DETAILED DESCRIPTION

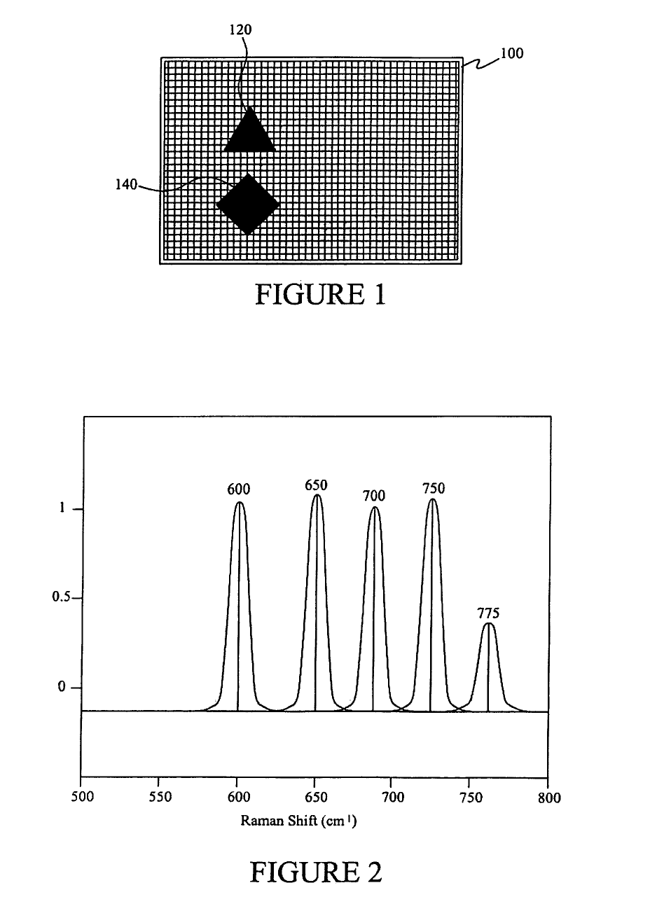

FIG. 1 is a schematic chemical image of a sample having a combination of two species. In FIG. 1, frame 100 represents a chemical image at a specific wavelength or Raman shift of a composition having a first specie 120 and a second specie 140. Frame 100 can be formed by combining several spectra into a chemical image. The specific wavelength or Raman shift frame can be defined by a number of pixels where each pixel is defined by it location (e.g., x, y) and intensity (I). Thus, each pixel in a wavelength or Raman shift frame can be defined as a function of I, x, y. According to one embodiment of the disclosure, frame 100 can be used to interactively subtract out background noise as well as spectral contribution from one or more species to obtain the spectral image of one specie.

FIG. 2 consists of reference spectra obtained of the pure components known to comprise the sample. Assuming that the composition of each of specie 120 and 140 is known, the Raman characteristics for each specie can be obtained. The Raman characteristic can include an expected wavelength for the Raman peak shift for each specie. In FIG. 2, Raman peaks for each of specie 120 and 140 are combined in one spectrum. Spectrum 200 shows peak Raman wavelengths for samples 120 and 140 and their normalized intensity. Specifically, each of peaks 600, 700 and 775 indicate a Raman shift for specie 120 and each of peaks 650 and 750 indicate a Raman shift for specie 140 of FIG. 1. The characteristic Raman peak for each specie identifies the specie's wavelengths/intensity relationship. Based on this information, pixels exhibiting the appropriate wavelength/intensity relationship can be attributed to one of the two species.

After identifying a characteristic Raman peak wavelength for each specie, the background wavelength for the frame should be defined. The background wavelength can be caused by intangibles of the optical devices such as signal-to-noise interference, and other common electro-optical losses. The background wavelength can also define a quantifiable intensity uniformly affecting all pixels in the chemical image frame 100. Once the intensity and the wavelength of background noise is identified, all pixels in the Chemical image frame that only relate to the background wavelength can be identified. Thereafter, all pixels defined by wavelength and intensity characteristics similar to that of the known Raman spectra of each specie can be identified.

Once the pixels directed exclusively to one of the first or second specie or the background have been identified, the remaining pixels can be attributed to identifying a combination of the first and the second species, thereby constituting a chemical interface of one or more species. Theses remaining pixels can be said to contain a contribution from each specie.

Once the function of each pixel in the frame is defined as one of background, first specie, second specie or a combination of first and second species, a spectral image can be constructed for one of the species by interactively subtracting contributions from the background and the other specie. In the exemplary embodiment of FIGS. 1 and 2, only two species are present. Thus, by subtracting pixels directed to background and second specie, a spectrum for the first specie can be constructed and compared to the corresponding reference spectrum. The degree to which the extracted spectrum of the residual image component matches the reference spectrum is a measure of the validity or quality of the interactive hyperspectral image subtraction. To further enhance the first specie's spectrum one can include additional pixels depicting contribution from both species. To this end, the pixels showing contribution from both species can be normalized to represent the contribution from each specie and filtered to remove the contribution from the second to isolate the first specie's contribution to the pixel.

The disclosed method and apparatus enable interactive visualization and comparison of different imaging modes. The interaction is direct and unobstructed. The embodiments disclosed here enable macro-to-micro image exploration as well as specific targeting of regions of interest. In addition, the ability to switch between imaging modes for the same regions allow comparisons that would otherwise not be possible, or alternatively, would be difficult and time consuming. These exemplary steps can be repeated to determine a spectra for the second specie. While the exemplary embodiments of FIGS. 1 and 2 are directed to a sample of only two species, the principles disclosed herein can be extended to a system of sample having multiple species.

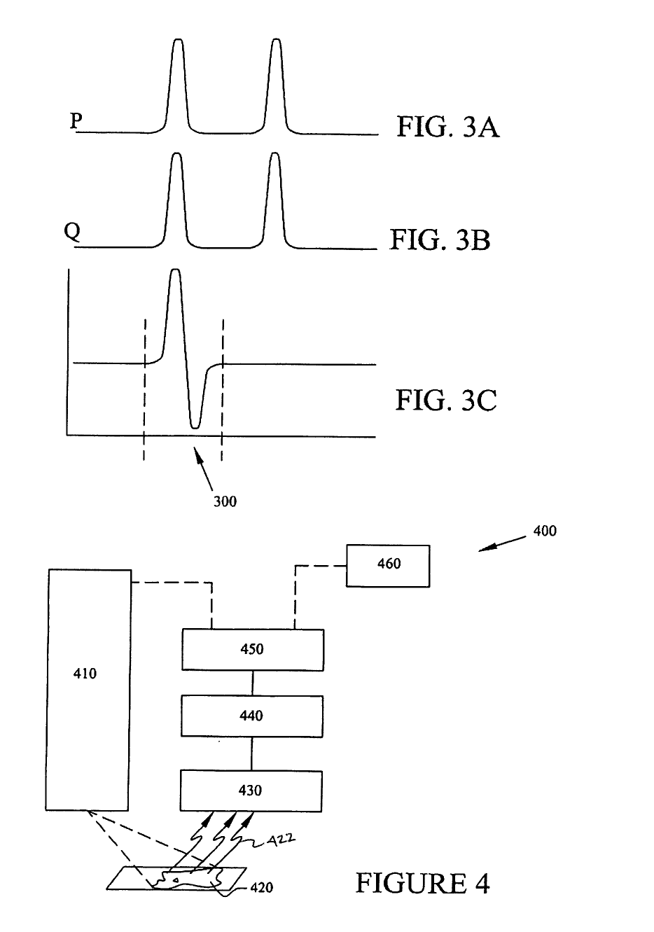

Moreover, the same principles can be extended to samples exhibiting a chemical interaction between the species. FIGS. 3A-3C illustrate the resulting spectrum from a chemical interaction of two spectra. Specifically, FIG. 3A shows the reference Raman spectrum for specie P and FIG. 3B shows the image extracted Raman spectrum for specie P. If species P chemically interacts with neighboring material, the spectrum resulting from the spectral subtraction of reference P from image extracted P can be expected to have a Raman spectrum revealing a chemical shift as shown in FIG. 3C. Thus, where a sample contains one or more chemically interacting compound species, the Raman peak shift for the compound can be detected as shown in FIGS. 3A-3C.

FIG. 4 is a schematic illustration of an exemplary apparatus according to one embodiment of the disclosure. In FIG. 4, apparatus 400 includes illumination source 410 for providing illumination photons of wavelength λ_{illum.} to sample 420 to provide interacted photons. Interacted photons 422 may include Fluorescence, reflection, transmission, emission and Raman photons. The interacted photons may have a different wavelength depending on the specie from which they emanate and the illumination wavelength. In the case where the interacted photons are Raman scattered photons, the wavelength of the interacted photons will reflect the characteristic Raman peak wavelength for said specie.

Sample 420 can have a plurality of species (not shown.) Further, the sample can be any biological, organic or inorganic sample suitable for spectral studies. Optical device 430 can receive and direct interacted photons to imaging device 440. The illumination source can be positioned above, near or below the sample. Optical device 430 may include gathering optics, optical train, macro-scope and electromechanical devices needed for its operation. Imaging device 440 may include, for example, an optical train for gathering and focusing interacted photons; one or more optical filters for rejecting photons of undesired wavelengths; an LCTF for obtaining spectral images of the sample; and a charge-coupled device for devising a chemical image based on the spectral images of the sample. Imaging device 440 can communicate with peripheral network devices (not shown) such as printers, video recorders or internet communication systems.

Processor 450 communicates with imaging device 440 and can be used to implement interactive hyperspectral image subtraction steps disclosed above. For example, the processor can be programmed to: (1) identify, for each of the first and second species, an appropriate Raman wavelength; (2) define at least one background wavelength for the frame; (3) identify pixels defined only by the background wavelength; (4) identify pixels defined only by the first specie or the second specie; (5) identify the remaining pixels, the remaining pixels defined by at least a combination of the first and second species; and (6) form a spectral image for the first specie. These steps can be implemented substantially simultaneously or sequentially. In an optional embodiment, the step of identifying the contribution from each of the first and the second specie for each of the remaining pixels may be implemented.

Processor 450 may communicate with operator 460 for interactive subtraction. In addition, the processor may communicate with illumination source 410 in order to increase or decrease illumination wavelength λ_{illum.} in response to operator 460 request or in response to programmed instructions.

While the principles of the disclosure have been disclosed in relation to specific exemplary embodiments, it is noted that the principles of the invention are not limited thereto and include all modification and variation to the specific embodiments disclosed herein.

What is claimed is:

1. A method for obtaining a spectral image of a first specie from a frame of a plurality of pixels defining a composition of the first specie with a second specie, comprising:
identifying, for each of the first and second species, an appropriate Raman wavelength;
defining at least one background wavelength for the frame;
identifying pixels defined only by background wavelength;
identifying pixels defined only by the first specie or the second specie;
identifying the remaining pixels, the remaining pixels defined by at least a combination of the first and second species; and
forming a spectral image for the first specie.

2. The method of claim 1, further comprising the step of identifying the contribution from each of the first and the second specie for each of the remaining pixels.

3. The method of claim 1, wherein the appropriate Raman wavelength defines a peak Raman wavelength;

4. The method of claim 1, wherein the first specie is a chemical element in a substantially pure form.

5. The method of claim 1, wherein the first specie is a chemical compound defined by a combination of more than one chemically pure element.

6. The method of claim 1, wherein the background wavelength defines an optical wavelength.

7. The method of claim 1, wherein the background wavelength contributes to all pixels.

8. The method of claim 1, wherein the background wavelength contributes to all chemical species present in the composition.

9. The method of claim 1, wherein the step of identifying pixels defined only by the first specie, further comprise identifying a Raman wavelength for the first specie, the Raman wavelength defined by a wavelength range and a peak having a peak intensity.

10. The method of claim 1, wherein the step of identifying pixels defined only by the second specie, further comprise identifying a Raman wavelength for the second specie, the Raman wavelength defined by a wavelength range and a peak having a peak intensity.

11. The method of claim 1, wherein the step of identifying the contribution from each of the first and the second specie for each of the remaining pixels further comprises comparing the Raman intensity of each pixel with a known peak Raman intensity for each of the first and the second specie.

12. The method of claim 1, wherein the step of forming a spectral image for the first specie further comprises forming a spectral images as a function of the background wavelength and the pixels defining the first specie.

13. The method of claim 1, further comprising forming a spectral image for the second specie as a function of the background wavelength and the pixels defining the second specie.

14. A method for obtaining a spectral image of first specie from a chemical image of said first specie in combination with a second specie, comprising:
providing a chemical image of a mixture of the first and second specie, the chemical image defined by a frame having a plurality of pixels;
identifying, for each of the first and second species, an appropriate Raman wavelength;
defining a background wavelength for the frame;
identifying pixels defined only by background wavelength;
identifying pixels defined by the peak Raman wavelength of the first specie or the second specie;
identifying a plurality of remaining pixels, the remaining pixels identifying a combination of the first and second species; and
forming a spectral image for the first specie.

15. The method of claim 14, further comprising identifying the contribution from each of the first and the second specie to each of the remaining pixels

16. The method of claim 14, wherein the peak Raman wavelength defines a peak Raman wavelength having a range.

17. The method of claim 14, wherein the first specie is a chemical element in a substantially pure form.

18. The method of claim 14, wherein the first specie is a chemical compound defined by a combination of more than one chemically pure element.

19. The method of claim 14, wherein the background wavelength defines an optical wavelength.

20. The method of claim 14, wherein the background wavelength contributes to all pixels.

21. The method of claim 14, wherein the background wavelength contributes to an intensity of each pixel.

22. The method of claim 14, wherein the step of identifying the contribution from each of the first and the second specie to each of the remaining pixels further comprises comparing the Raman intensity of each pixel with a known intensity for each of the first and the second specie.

23. The method of claim 14, wherein the step of forming a spectral image for the first specie further comprises forming a spectral images as a function of the background wavelength and the pixels defining the first specie.

24. The method of claim 14, further comprising forming a spectral image for the second specie as a function of the background wavelength and the pixels defining the second specie.

25. An apparatus for obtaining a spectral image of a first specie from a chemical image of said first specie with a second specie, comprising:
an illumination source for illuminating the sample with a plurality of excitation photons and producing a plurality of interacted photons;
an optical device for receiving and directing the plurality of interacted photons to an imaging device for forming a chemical image define by at least one frame having a plurality of pixels; and
a processor in communication with the imaging device, the processor adapted to execute instructions for
identifying, for each of the first and second species, an appropriate Raman wavelength;
defining at least one background wavelength for the frame;
identifying pixels defined only by background wavelength;
identifying pixels defined only by the first specie or the second specie;
identifying the remaining pixels, the remaining pixels defined by at least a combination of the first and second species; and
forming a spectral image for the first specie.

26. The apparatus of claim 24, wherein the instructions further include identifying the contribution from each of the first and the second specie to each of the remaining pixels

27. The apparatus of claim 24, wherein the appropriate Raman wavelength defines a peak Raman wavelength;

28. The apparatus of claim 24, wherein the first specie is a chemical element in a substantially pure form.

29. The apparatus of claim 24, wherein the first specie is a chemical compound defined by a combination of more than one chemically pure element.

30. The apparatus of claim 24, wherein the background wavelength defines an optical wavelength.

31. The apparatus of claim 24, wherein the background wavelength contributes to all pixels.

32. The apparatus of claim 24, wherein the background wavelength contributes to all chemical species present in the composition.

33. The apparatus of claim 24, wherein the step of identifying pixels defined only by the first specie, further comprise identifying a Raman wavelength for the first specie, the Raman wavelength defined by a wavelength range and a peak having a peak intensity.

34. The apparatus of claim 24, wherein the step of identifying pixels defined only by the second specie, further comprise identifying a Raman wavelength for the second specie, the Raman wavelength defined by a wavelength range and a peak having a peak intensity.

35. The apparatus of claim 24, wherein the step of identifying the contribution from each of the first and the second specie for each of the remaining pixels further comprises comparing the Raman intensity of each pixel with a known peak Raman intensity for each of the first and the second specie.

36. The apparatus of claim 24, wherein the step of forming a spectral image for the first specie further comprises forming a spectral images as a function of the background wavelength and the pixels defining the first specie.

37. The apparatus of claim 24, wherein the step of forming a spectral image for the second specie as a function of the background wavelength and the pixels defining the second specie.
